(19) United States
(12) Patent Application Publication
(10) Pub. No.: US 2006/0208344 A1
(43) Pub. Date: Sep. 21, 2006

(54) Lead frame panel and method of packaging semiconductor devices using the lead frame panel

(76) Inventors: Hei Ming Shiu, Hong Kong (HK); Gor Amie Lai, Hong Kong (HK); Fei Ying Wong, Hong Kong (HK)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/081,965

(22) Filed: Mar. 16, 2005

(51) Int. Cl. H01L 23/495

(52) U.S. Cl. 257/666

(57) ABSTRACT

A lead frame panel (40) includes a body (42) having an array of die support areas (44) for receiving respective semiconductor dies. The die support areas (44) are surrounded by leads (46). Adjacent rows of leads are coupled by half-etched connection bars (48), such that each half-etched portion of the connection bars (48) forms a channel into which a mold compound (54) is injected.

### BACKGROUND OF THE INVENTION

The present invention relates to semiconductor packaging in general and more specifically to a lead frame panel and a method of packaging a plurality of semiconductor devices using such a lead frame panel.

Leadless packages having reduced package footprint and profile have been developed to address certain limitations of traditional lead frame packages. During packaging, either strips or arrays of circuits are packaged at the same time. In array packaging, lead frame panels having an array of lead frames are used. FIGS. 1 and 2 illustrate a conventional lead frame panel 10 and a mold 20 used in the manufacture of leadless packages.

Referring first to FIG. 1, the lead frame panel 10 has a body 12 defining a plurality of die support areas 14 for respective ones of a plurality of semiconductor die. Each die support area 14 is surrounded by a plurality of leads 16. The die support areas 14 are arranged in rows. A space 18 is provided between adjacent rows to accommodate a mold runner. Leadless packages are formed by attaching semiconductor dies to respective ones of the die support areas 14, electrically connecting the dies to leads 16, coupling the lead frame panel 10 to the mold 20 of FIG. 2 and performing a molding operation to encapsulate the semiconductor dies.

Referring now to FIG. 2, the mold 20 includes a plurality of cavities 22 corresponding to respective ones of the die support areas 14 and a plurality of runner passages 24 corresponding to respective ones of the spaces 18 on the lead frame panel 10. Each runner passage 24 is coupled to a corner of one of the adjacent cavities 22 via respective ones of a plurality of gates 26. The molding operation involves injecting a mold compound through the runner passages 24 and the gates 26 and then into the cavities 22. The lead frame panel 10 is separated from the mold 20 when the cavities 22 are filled and the mold compound has cooled sufficiently to solidify.

FIG. 3 shows the lead frame panel 10 of FIG. 1 after the molding operation. The lead frame panel 10 includes a plurality of leadless packages 28 corresponding to the respective semiconductor dies attached to the die support areas 14 and a plurality of mold runners 30 formed over the respective spaces 18.

Referring again to FIG. 1, the spaces 18 on the lead frame panel 10 occupy valuable area, resulting in wastage of lead frame material, which adds to the cost of manufacturing. Thus, a need exists for a high density lead frame panel for the manufacture of packaged semiconductor devices.

Accordingly, it is an object of the present invention to provide a high density lead frame panel for the manufacture of packaged semiconductor devices and a method of packaging a plurality of semiconductor devices using such a lead frame panel.

### BRIEF DESCRIPTION OF THE DRAWINGS

The following detailed description of a preferred embodiment of the invention will be better understood when read in conjunction with the appended drawings. The present invention is illustrated by way of example and is not limited by the accompanying figures, in which like references indicate similar elements.

FIG. 1 is a perspective view of a conventional lead frame panel;

FIG. 2 is a perspective view of a conventional mold used with the lead frame panel of FIG. 1 to encapsulate semiconductors;

FIG. 3 is a perspective view of the lead frame panel of FIG. 1 after a molding operation;

FIG. 4 is a perspective view of a lead frame panel in accordance with an embodiment of the present invention;

FIG. 5 is an enlarged perspective view of a portion of the lead frame panel of FIG. 4;

FIG. 6 is an enlarged cross-sectional view of a portion of the lead frame panel along a line X-X in FIG. 5;

FIG. 7 is a perspective view of a mold in accordance with an embodiment of the present invention;

FIG. 8 is a perspective view illustrating the flow of a mold compound over a lead frame panel in accordance with an embodiment of the present invention;

FIG. 9 is an enlarged perspective view of a portion of the lead frame panel of FIG. 8;

FIG. 10 is a perspective view of the lead frame panel of FIG. 4 after a molding operation; and

FIG. 11 is a flowchart illustrating a method of packaging a plurality of semiconductor devices in accordance with an embodiment of the present invention.

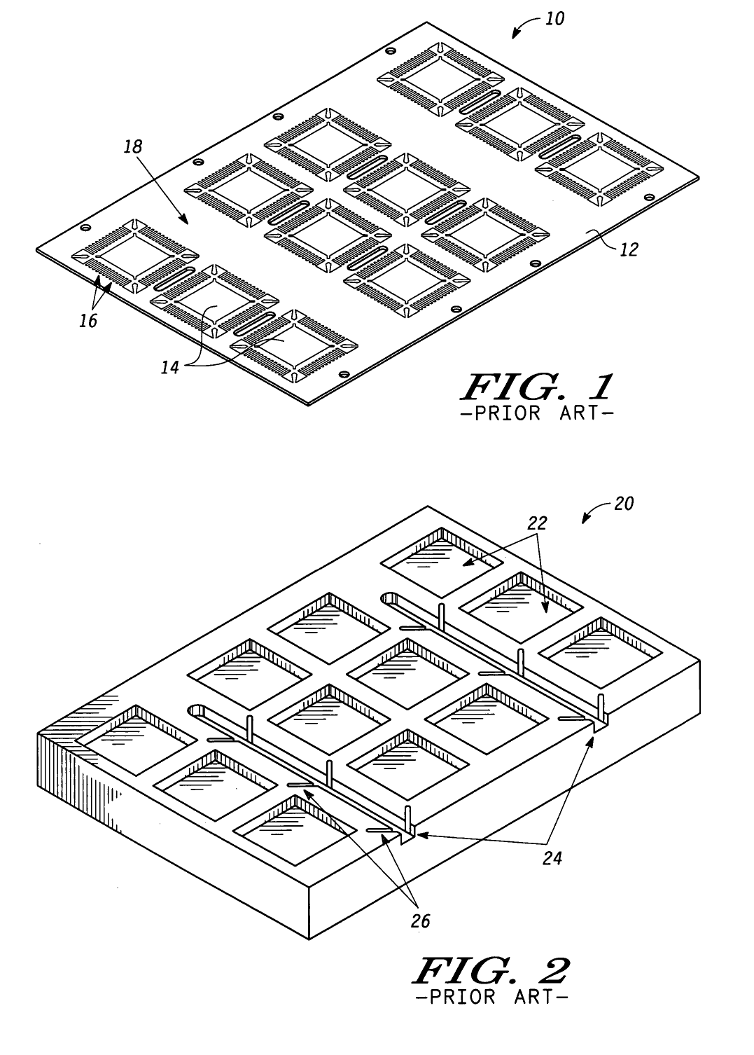

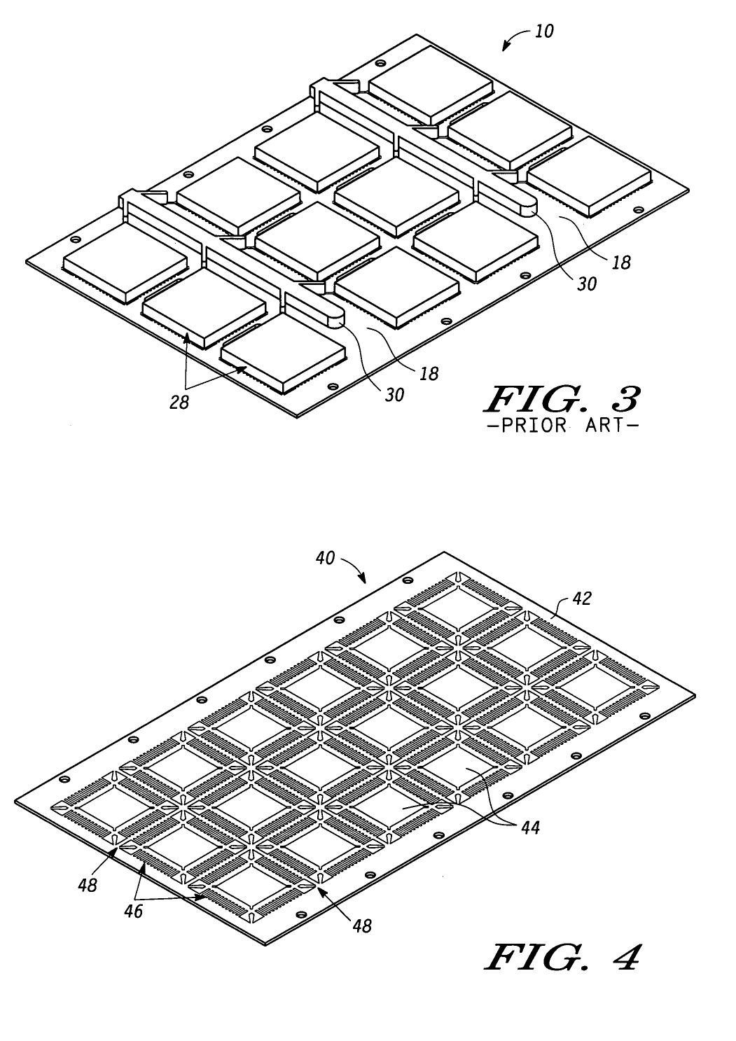

### DETAILED DESCRIPTION OF THE PREFERRED EMBODIMENTS

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

The present invention provides a lead frame panel including a body having a plurality of die support areas for receiving respective ones of a plurality of semiconductor dies, and a plurality of leads surrounding each of the die support areas. A plurality of half-etched connection bars couple adjacent ones of the plurality of leads. The half-etched portion of each connection bar forms a channel for a mold compound to flow therethrough.

The present invention further provides a method of packaging a plurality of semiconductor devices, including the steps of providing a lead frame panel having a body with a plurality of die support areas for receiving respective ones of a plurality of semiconductor dies, and a plurality of leads surrounding each of the die support areas. A plurality of half-etched connection bars couple adjacent ones of the plurality of leads, and the half-etched portion of each connection bar forms a channel for a mold compound to flow therethrough. At least one semiconductor die is attached to each of the die support areas. The semiconductor dies are electrically coupled to respective ones of the plurality of leads and a mold compound is injected into the channels of the half-etched connection bars. The mold compound encapsulates at least one side of the dies and the leads.

FIG. 4 illustrates a lead frame panel 40 in accordance with an embodiment of the present invention. The lead frame panel 40 comprises a body 42 defining a plurality of die support areas 44 for respective ones of a plurality of semiconductor die and a plurality of leads 46 surrounding each of the respective die support areas 44. The leads 46 of adjacent die support areas 44 extend outwardly (toward the die support areas 44) from connection bars 48. The leads 46 serve as Inputs and Outputs (IOs) for semiconductor dies that are attached to respective ones of the die support areas 44. In the embodiment shown, the body 42 has an array of die support areas 44 arranged in a 3×6 matrix. However, those of skill in the art will understand that the present invention is not limited by the arrangement or number of the die support areas 44. The lead frame panel 40 may be formed from a copper sheet or strip via etching or stamping, as is known in the art. The lead frame panel 40 also may be plated.

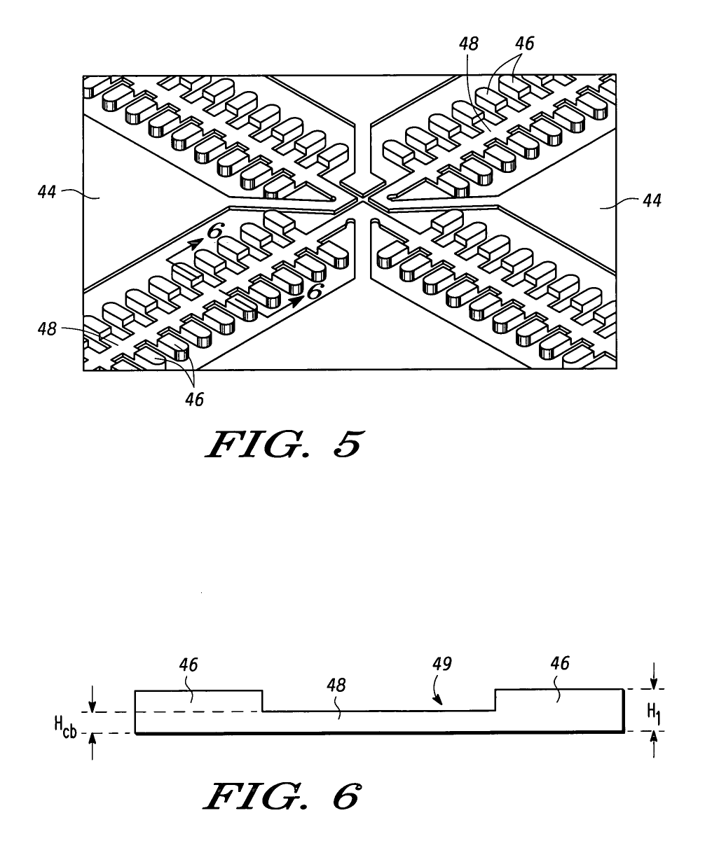

Referring now to FIG. 5, an enlarged view of a portion A of the lead frame panel 40 of FIG. 4 is shown. As can be seen, a portion of the leads 46 and the the connection bars 48 are etched such that channels 49 (see FIG. 6) are formed between opposing pairs of the leads 46. As discussed in more detail below, during a semiconductor encapsulation process, mold compound flows through the channels 49.

FIG. 6 is an enlarged cross-sectional view of the lead frame panel 40 along a line X-X in FIG. 5. Opposing leads 46 are coupled by a half-etched connection bar 48 and the half-etched portion forms a channel 49. In this particular example, the distal portions (in relation to the connection bar) of the leads 46 have a thickness Hₗ of about 0.2 mm, while the proximate portions of the leads 46 and the connection bars 48 have a thickness H_{cb} of about 0.1 mm. However, it should be understood that the present invention is not limited to these particular dimensions of the leads and connection bars.

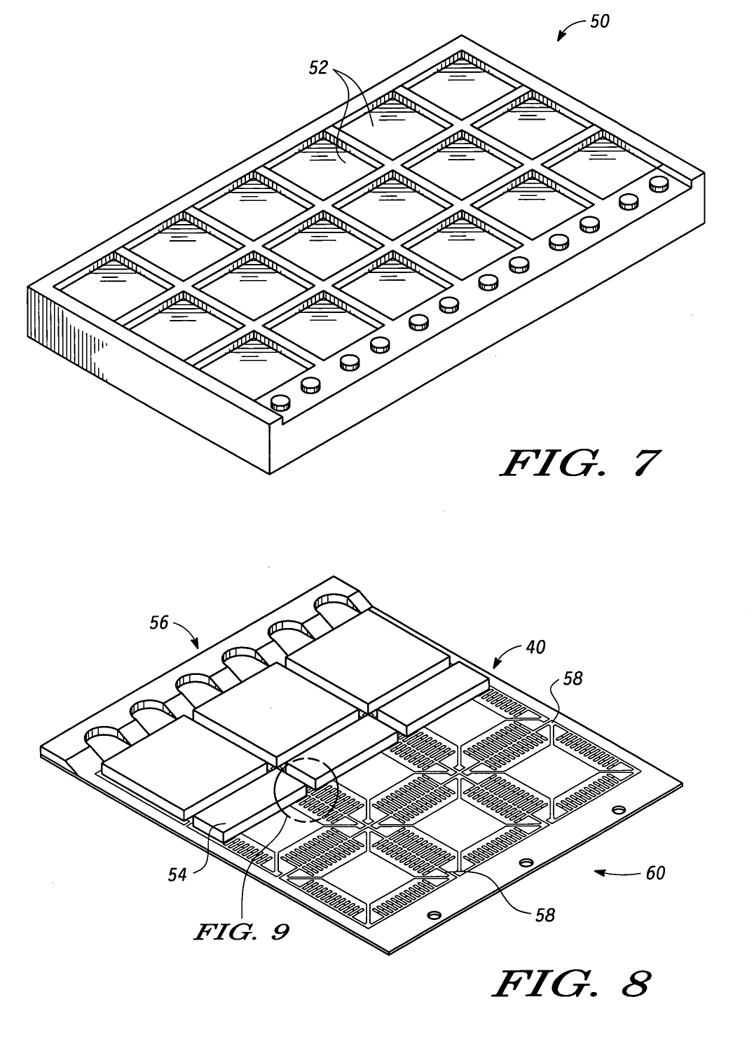

Referring again to FIG. 4, leadless packages are formed by attaching semiconductor dies to respective ones of the die support areas 44, coupling the lead frame panel 40 to a mold 50 illustrated in FIG. 7 and performing a molding operation to encapsulate the semiconductor dies. FIG. 7 shows a mold 50 that has a plurality of cavities 52 corresponding to respective ones of the die support areas 44 in FIG. 4. The molding or encapsulation operation involves injecting a mold compound into the cavities 52. FIG. 8 shows the flow of a mold compound 54 over the lead frame panel 40. For illustration purposes, the mold 50 is not shown. As can be seen, the mold compound 54 is injected from a first side 56 of the body 42 of the lead frame panel 40 into the channels 49 of the half-etched connection bars 48. In the embodiment shown, one or more vacuum vents 58 are disposed on a second side 60 of the lead frame panel 40 to facilitate the filling up of the cavities 52 in the mold 50. Vacuum vents also may be provided on the other sides (excluding the first side) of the lead frame panel 40. Those of skill in the art will understand that the present invention is not limited by the number of vacuum vents or the position of each vacuum vent in relation to the lead frames.

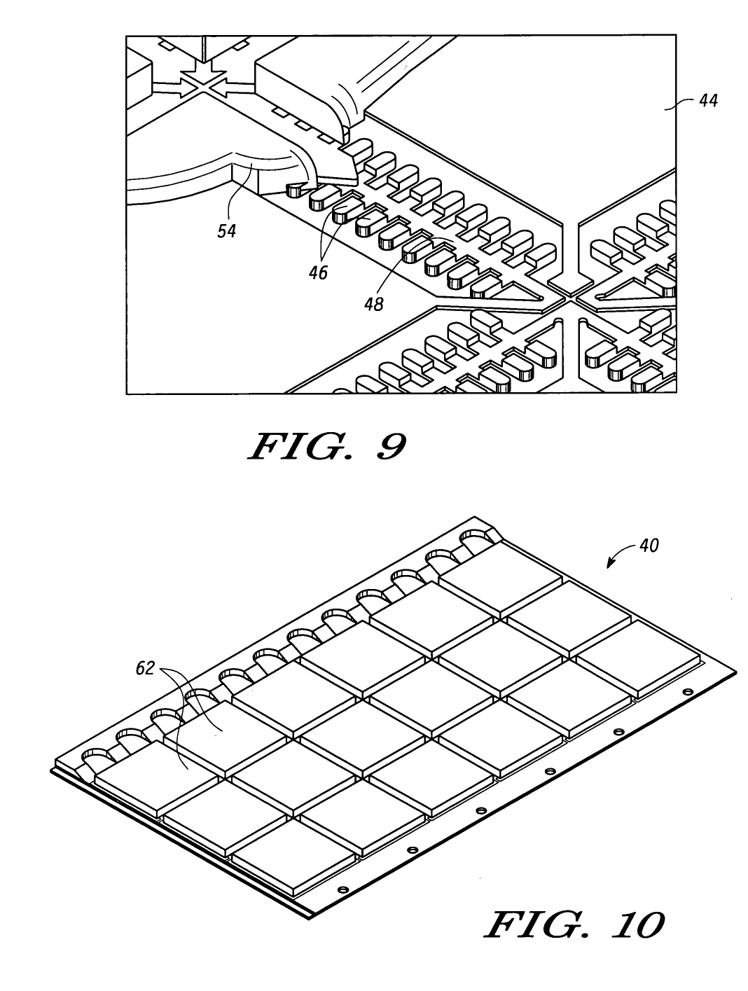

Referring now to FIG. 9, an enlarged view of a portion B of the lead frame panel 40 of FIG. 8 is shown. As can be seen, the mold compound 54 flows through the channels 49 provided by the half-etched connection bars 48, between the leads 46 surrounding the die support areas 44, and into the cavities 52 in the mold 50 during the molding operation.

The lead frame panel 40 is separated from the mold 50 when the cavities 52 are filled and the mold compound 54 has cooled sufficiently to solidify. FIG. 10 shows the lead frame panel 40 of FIG. 4 after the molding operation. The lead frame panel 40 includes a plurality of leadless packages 62 corresponding to respective ones of the semiconductor dies attached to the die support areas 44. The leadless packages 62 may be separated by punching or saw singulating.

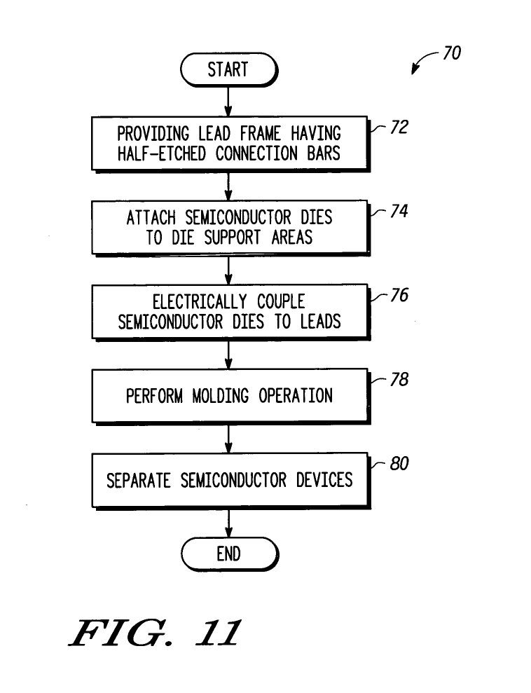

FIG. 11 is a flowchart illustrating a method 70 of packaging a plurality of semiconductor devices in accordance with an embodiment of the present invention. The method 70 begins by providing a lead frame (step 72). The lead frame includes a body having a plurality of die support areas for receiving respective ones of a plurality of semiconductor dies. A plurality of leads surrounds each of the respective die support areas. A plurality of half-etched connection bars couple respective adjacent ones of the plurality of leads. Each half-etched connection bar provides a channel for a mold compound to flow therethrough. Semiconductor dies are attached to respective ones of the die support areas (step 74) and electrically coupled to respective ones of the plurality of leads (step 76). Thereafter, an encapsulation process is performed in which a mold compound is injected into the mold and moves by way of the half-etched connection bars over the dies (step 78). The encapsulated semiconductor devices then are separated such as by punching or saw singulation (step 80).

As is evident from the foregoing discussion, the present invention provides a lead frame panel and a method of packaging a plurality of semiconductor devices, which has benefits over existing products and processes. For example, by providing an alternative passage for the flow of mold compound during molding operations, which does away with the need to set aside valuable space on lead frame panels for mold runners, the present invention makes available more area on the lead frame panel for individual lead frames, making it possible to pack a greater number of lead frames on a single lead frame panel. Thus, a greater number of packaged devices can be assembled from a single lead frame panel with the present invention, thereby reducing wastage of lead frame material and consequently, the cost of manufacturing packaged devices.

There has been provided, in accordance with the invention, a lead frame panel and a method of packaging a plurality of semiconductor devices that fully meets the advantages set forth previously. Although the invention has been described and illustrated with reference to specific embodiments thereof, it is not intended that the invention be limited to these illustrative embodiments. Those skilled in the art will recognize that modifications and variations can be made without departing from the spirit of the invention. As addressed earlier, the present invention is not limited by the arrangement or number of die support areas on the lead frame panel. Nor is the present invention limited by the thickness of the leads or that of the half-etched connection bars. It should be understood that the present invention is also not limited by the number of vacuum vents or the position of each vacuum vent in relation to the lead frames. Therefore, it is intended that this invention encompass all such variations and modifications as fall within the scope of the appended claims.

1. A lead frame panel comprising:
a body having a plurality of die support areas for receiving respective ones of a plurality of semiconductor dies;
a plurality of leads surrounding each of the die support areas; and
a plurality of half-etched connection bars that couple adjacent ones of the plurality of leads, wherein the half-etched portion of each connection bar forms a channel for a mold compound to flow therethrough.

2. The lead frame panel of claim 1, wherein the mold compound is injected from a first side of the body into said channels.

3. The lead frame panel of claim 2, further comprising a vacuum vent disposed on at least one other side of the body.

4. The lead frame panel of claim 2, further comprising a vacuum vent disposed on more than one other side of the body.

5. The lead frame panel of claim 1, wherein the half etched connection bars have a thickness of about 0.2 mm and the half-etched portions have a thickness of about 0.1 mm.

6. The lead frame panel of claim 1, wherein the body has an array of die support areas.

7. A lead frame panel comprising:
a body having an array of die support areas for receiving respective ones of a plurality of semiconductor dies;
a plurality of leads surrounding each of the die support areas;
a plurality of half-etched connection bars that couple adjacent ones of the plurality of leads, wherein the half-etched portion of each connection bar forms a channel for a mold compound to flow therethrough;
a mold compound receiving channel located on one side of the body, wherein the mold compound is injected into the mold compound receiving channel; and
a vacuum vent disposed at least one other side of the body, wherein the mold compound is injected into the mold compound receiving channel and is drawn through the connection bar channels by a vacuum force from the vacuum vent.

8. A method of packaging a plurality of semiconductor devices, comprising:
providing a lead frame panel including:
a body with a plurality of die support areas for receiving respective ones of a plurality of semiconductor dies;
a plurality of leads surrounding each of the die support areas; and
a plurality of half-etched connection bars that couple adjacent ones of the plurality of leads, wherein the half-etched portion of each connection bar forms a channel for a mold compound to flow therethrough;
attaching at least one semiconductor die to each of the die support areas;
electrically coupling the semiconductor dies to respective ones of the plurality of leads; and
injecting a mold compound into the channels of the half-etched connection bars, wherein the mold compound encapsulates at least one side of the dies and the leads.

9. The method of packaging a plurality of semiconductor devices of claim 8, further comprising separating the plurality of encapsulated semiconductor devices.

10. The method of packaging a plurality of semiconductor devices of claim 9, wherein the separating step comprises saw singulating the lead frame panel along the channels.

11. The method of packaging a plurality of semiconductor devices of claim 9, wherein the separating step comprises punching the lead frame panel along the channels.

12. The method of packaging a plurality of semiconductor devices of claims 8, wherein the lead frame panel receives the mold compound on a first side and includes a vacuum vent on at least one other side for drawing the mold compound through the channels.
